(19) United States
(12) Patent Application Publication
(10) Pub. No.: US 2007/0040231 A1
(43) Pub. Date: Feb. 22, 2007

(54) Partially etched leadframe packages having different top and bottom topologies

(76) Inventors: Kieran P. Harney, Andover, MA (US); John R. Martin, Foxborough, MA (US); Lawrence E. Felton, Hopkinton, MA (US)

Correspondence Address: BROMBERG & SUNSTEIN LLP, 125 SUMMER STREET, BOSTON, MA, 02110-1618, US

(21) Appl. No.: 11/338,439

(22) Filed: Jan. 24, 2006

Related U.S. Application Data
(60) Provisional application No. 60/708,449, filed on Aug. 16, 2005.

(51) Int. Cl. H01L 29/84

(52) U.S. Cl. 257/415

(57) ABSTRACT

A package for a micro-electromechanical (MEMS) device is described. A premolded leadframe base has opposing top and bottom surfaces. Each surface is defined by a topology having at least one electrically conductive portion and at least one electrically non-conductive portion, and the topology of the top surface differs from the topology of the bottom surface.

This application claims priority from U.S. Provisional Patent Application 60/708,449, filed Aug. 16, 2005, which is incorporated herein by reference.

### FIELD OF THE INVENTION

The invention relates to micro-electromechanical system (MEMS) device packaging, specifically, to premolded leadframe packages for such devices.

### BACKGROUND ART

Many micro-electromechanical systems (MEMS) devices are intended to interact with their environment. For example, MEMS microphones develop an electrical signal in response to the surrounding acoustic environment. Use of MEMS microphones rather than the earlier electret-condenser microphones (ECM) has come to be appreciated for many applications, such as mobile phones.

FIG. 1 schematically shows an unpackaged MEMS microphone 10 which includes a static backplate 12 that supports and forms a variable capacitor with a flexible diaphragm 14. In specific applications, the backplate 12 may be formed from single crystal silicon, while the diaphragm 14 may be formed from deposited polysilicon. To facilitate operation, the backplate 12 may have multiple throughholes 16 that lead to a back-side cavity 18.

Audio signals cause the diaphragm 14 to vibrate, thus producing a changing capacitance. On-chip or off-chip circuitry converts this changing capacitance into electrical signals that can be further processed. It should be noted that discussion of the microphone 10 shown in FIG. 1 is for illustrative purposes only.

FIG. 2A schematically shows a cross-sectional view of a packaged microphone in which the cross-sectional view is across line A-A of FIG. 2B, which schematically shows a bottom view of the packaged microphone shown in FIG. 2A. The packaged microphone includes a microphone chip (also identified by reference number 10), such as that shown in FIG. 1, and a circuit chip 20 that controls and coordinates operation of the microphone chip 10. These chips 10 and 20 are mounted within a leadframe package 22 having a base portion 24 (with a bottom surface 26 and a top surface, not shown), and a conductive lid 30 secured to the base 24. In specific applications, the conductive lid 30 may be formed from a conductive plastic, or non-conductive plastic having a metal plating layer, or from a formed metal housing.

Further explanation of various aspects of MEMS microphones is provided in the following, which are incorporated herein by reference:

The disclosures of each of these patent applications are incorporated herein, in their entireties, by reference.

MICROPHONE WITH PREMOLDED TYPE PACKAGE, naming Lawrence Felton, Kieran Harney, and John Martin as inventors, assigned attorney docket number 2550/A74, filed Aug. 16, 2005, and having Ser. No. 60/708,449,
MICROPHONE WITH IRREGULAR DIAPHRAGM, naming Jason Weigold as inventor, assigned attorney docket number 2550/A76, filed Aug. 23, 2005, and having Ser. No. 60/710,517,
MULTI-MICROPHONE SYSTEM, naming Jason Weigold and Kieran Harney as inventors, assigned attorney docket number 2550/A77, filed Aug. 23, 2005, and having Ser. No. 60/710,624,
MICROPHONE SYSTEM, naming Kieran Harney as inventor, assigned attorney docket number 2550/A78, filed Aug. 23, 2005, and having Ser. No. 60/710,515,
MICROPHONE WITH ENLARGED BACK-VOLUME, naming Kieran Harney as inventor, assigned attorney docket number 2550/A89, filed Nov. 28, 2005, and having Ser. No. 60/740,169.

The performance of MEMS devices such as microphones, switches, accelerometers, pressure sensors, and fluid composition sensors can be influenced by their packaging. MEMS packaging also has to satisfy multiple other criteria including, for example, system integration, strength, low cost, ease of fabrication and assembly, reliability, small size, thermal factors, electrical interconnection, etc. For example, a MEMS package may typically be intended to be physically and electrically attached to a larger printed circuit board (PCB) assembly.

### SUMMARY OF THE INVENTION

A representative embodiment of the present invention includes a package for a micro-electromechanical (MEMS) device, and a corresponding method for producing such a package. A premolded leadframe base has opposing top and bottom surfaces. Each surface is defined by a topology having at least one electrically conductive portion and at least one electrically non-conductive portion, and the topology of the top surface is substantially different from the topology of the bottom surface.

In a further embodiment, at least one electrically conductive portion on the top surface is connected to at least one electrically conductive portion on the bottom surface. Embodiments may also include a device cover coupled to the leadframe base so that the cover and the base together define an interior volume containing one or more MEMS devices. The device cover can also serve to shield devices within the interior volume from electromagnetic interference (EMI). One or both of the device cover and the leadframe base may include an opening adapted to allow sound to enter the interior volume. Embodiments may also include a MEMS microphone die coupled to the leadframe base, and/or an ASIC die coupled to the leadframe base.

### BRIEF DESCRIPTION OF THE DRAWINGS

FIG. 1 schematically shows a typical unpackaged MEMS microphone.

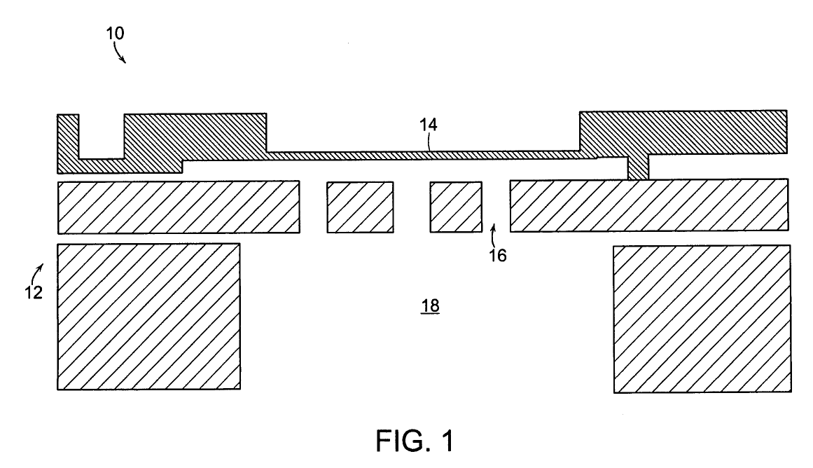

FIG. 2A schematically shows a cross-sectional view of a packaged MEMS microphone

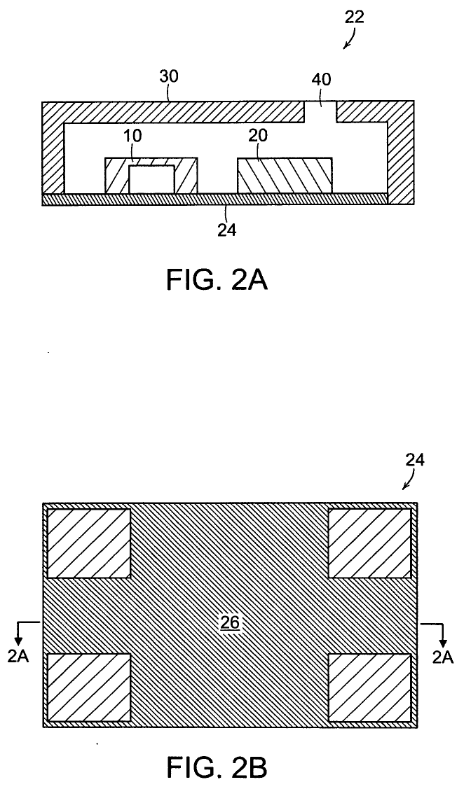

FIG. 2B schematically shows a bottom view of the packaged MEMS microphone shown in FIG. 2A.

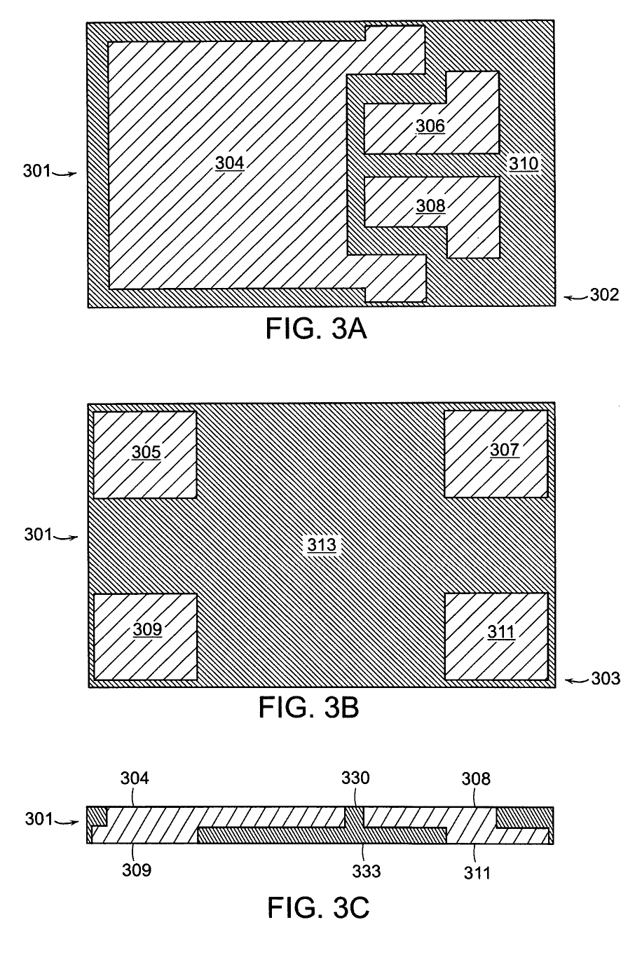

FIGS. 3A-C shows top plan, bottom plan, and cross-sectional views of a premolded leadframe base having different top and bottom electrical topologies according to one specific embodiment of the present invention.

FIGS. 4A-B shows a top plan view and cross-sectional view of a MEMS microphone package using the leadframe base of FIG. 1.

FIG. 5 illustrates various process steps in producing a premolded leadframe package having different top and bottom electrical topologies according to one specific embodiment.

FIGS. 6 A-F shows a cross-section view of a premolded leadframe base being produced according to the process in FIG. 5.

### DETAILED DESCRIPTION OF SPECIFIC EMBODIMENTS

Embodiments of the present invention are directed to packaging MEMS applications such as MEMS microphone applications in a premolded leadframe package. In specific embodiments, the leadframe base is developed to have substantially different electrical topologies on its top and bottom surfaces. That is, the electrical topologies will be non-trivially different in some significant way that is immediately apparent. Thus, the electrical topology of the top surface can be optimized to accommodate the structures contained within the package—e.g., a MEMS die, an ASIC die, other structures such as capacitors, etc., and their interconnections. And in the same leadframe base, the electrical topology of the bottom surface can be differently optimized for interconnection of the package as a whole to larger system structures—e.g., for electrical connection with and structural mounting on a surface mount printed circuit board within a mobile phone.

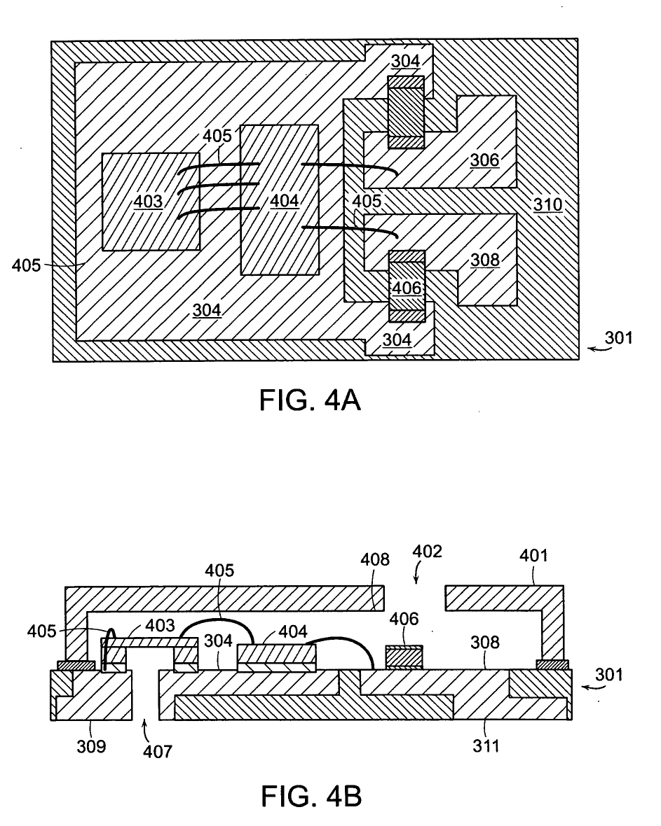

FIGS. 3A-C shows top plan, bottom plan, and cross-sectional views of a premolded leadframe base 301 having different top and bottom electrical topologies according to one specific embodiment of the present invention. The top surface 302 includes various different electrically conductive regions 304, 306 and 308 separated by a top non-conductive region 310. In the embodiment shown in FIG. 3, each of the electrically conductive regions 304, 306 and 308 is isolated and distinct from the other electrically conductive regions so that each may be at a different electrical potential level. For example, top conductive region 304 may be at ground potential, top conductive region 306 might be at rail voltage V_{dd}, and top conductive region 308 may be at output voltage Vₒᵤₜ.

The bottom surface 303 also includes various different electrically conductive regions 305, 307, 309 and 311 separated by a bottom non-conductive region 313. As can be seen in cross-sectional view FIG. 3C, top conductive region 304 connects through to bottom conductive region 309 (and also to bottom conductive region 305, not shown), which would be at some mutual level of electrical potential, for example, chassis ground. Similarly, the separate top conductive region 308 connects through to bottom conductive region 311, which would be at some different mutual level of electrical potential, for example, output voltage Vₒᵤₜ (as does the separate top conductive region 306 to bottom conductive region 307, not shown, at some third mutual level of electrical potential, for example, rail voltage V_{dd}).

As is apparent in FIGS. 3A-C, the shapes and dispositions of the different electrical regions on the bottom surface 303 of the leadframe base 301 are independent of the shapes and dispositions of the different electrical regions on the top surface 302. Thus, the specific electrical topology of each surface can be optimized for the devices and structures which will be mechanically and electrically coupled to each.

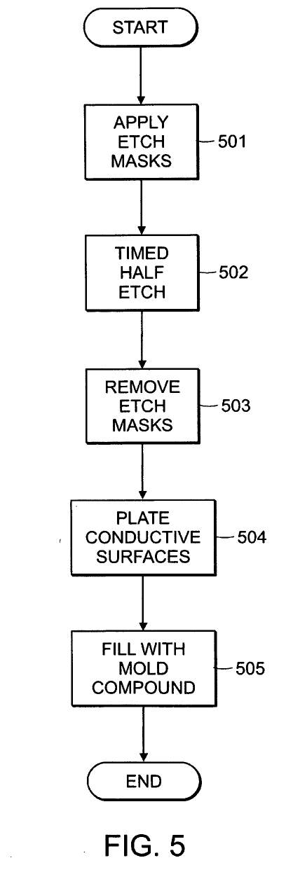

FIGS. 4A-B shows a top plan view and cross-sectional view of a MEMS microphone package using the leadframe base 301 of FIG. 3. Attached to the leadframe base 301 is a cover 401 (not shown in FIG. 4A) including a cover opening 402 which allows environmental sound into the package. The cover opening 402 may include a screen or other material that is basically transparent to sound, but keeps particles and debris from entering the package. The cover 401 may be electrically conductive to shield the interior contents from static electricity and stray electromagnetic interference (EMI).

Together the cover 401 and leadframe base 301 define an interior volume which contains the various interior structures of the package. In one specific embodiment, the leadframe base 301 may be substantially flat and the cover 401 may be in the form of an open ended box. In another specific embodiment, the leadframe base 301 may be in the form of an open ended box such that a substantially flat cover 401 may be fitted over it to define the interior volume. FIG. 4 shows a MEMS die 403 such as a MEMS microphone and an ASIC package 404 which may contain associated electronics such as a microphone amplifier, both of which are physically mounted on and electrically connected to a first top electrical region 304. Other components, for example filter capacitor 406, may couple from one top conductive region 308 to another top conductive region 304.

In the embodiment shown in FIG. 4B, the MEMS die 403 is mounted over a base acoustic port 407 configured to allow sound to enter the interior volume of the package. Like the cover opening 402, the base acoustic port 407 may be covered by a screen or other acoustically transparent material to prevent debris from entering the package. An embodiment like the one shown in FIG. 4 with both a cover opening 402 and base acoustic port 407, may be used as a directional microphone application. Other embodiments may have only one opening, either a cover opening 402 or a base acoustic port 407.

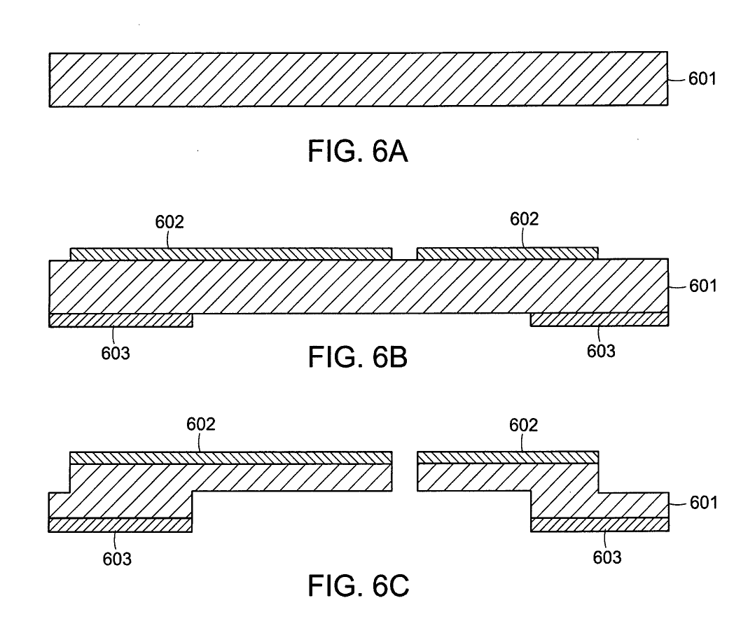

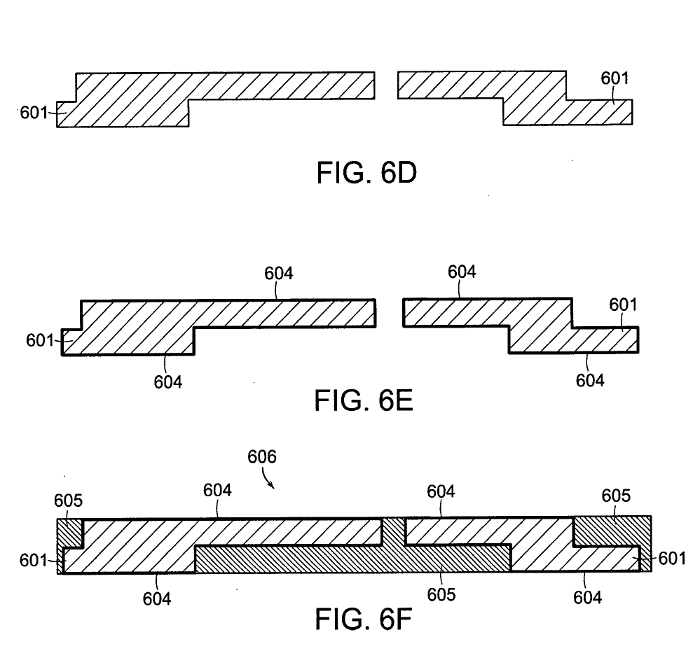

FIG. 5 illustrates various process steps in producing a premolded leadframe package having different top and bottom electrical topologies according to one specific embodiment. FIGS. 6 A-F shows a cross-section view of a premolded leadframe base being produced according to the process in FIG. 5. Starting from a block of conductive material 601 (e.g., copper, aluminum, or conductive metal alloy), shown in FIG. 6A, having approximately the desired size and geometry of the end leadframe base, top etch mask 602 and bottom etch mask 603 are applied to the top and bottom surfaces respectively, FIG. 6B and step 501. The top etch mask 602 covers some regions and exposes other regions of the top surface of the conductive material 601. The bottom etch mask 603 has a different shape so as to cover some regions and expose other regions of the bottom surface in a substantially different form than the top surface.

A timed half-etching step 502 is performed to remove the exposed conductive material 601 left by the top etch mask 602 and bottom etch mask 603. The half-etching step 502 is timed to allow the exposed conductive material to be etched away to a desired depth, for example, halfway through the block to create a masked block of partially etched conductive material 601, as shown in FIG. 6C. The top etch mask 602 and bottom etch mask 603 are then removed, step 503, leaving an unmasked block of partially etched conductive material 601, as shown in FIG. 6D.

The higher non-inset portions shown in FIG. 6D will ultimately be conductive surface regions on the top and bottom surfaces, while the inset regions will ultimately correspond to non-conductive regions. In some embodiments, the surfaces of the partially etched conductive block 601 may further be plated with a suitable material such as nickel-palladium-gold as is known in the art, step 504. The partially etched regions of conductive block 601 can now be filled with mold compound, step 505, for example, using liquid polymer technology. This completes the creation of a pre-molded leadframe base 606 having different electrical topologies on its top and bottom surfaces.

Such a premolded leadframe base can then be further assembled into a finished product. For example, structures can be added to the leadframe base to hold one or more MEMS dies, such as a MEMS microphone die. Structures can also be added to the leadframe base to hold one or more ASIC dies containing electronics to interface with the MEMS die. Such dies can be mounted to the leadframe base, and a cover (such as the cover 401 in FIG. 4) can be connected to the base.

Although various exemplary embodiments of the invention have been disclosed, it should be apparent to those skilled in the art that various changes and modifications can be made which will achieve some of the advantages of the invention without departing from the true scope of the invention.

What is claimed is:

1. A package for a micro-electromechanical (MEMS) device comprising:
a premolded leadframe base having opposing top and bottom surfaces, each surface being defined by a topology having at least one electrically conductive portion and at least one electrically non-conductive portion,
wherein the topology of the top surface is substantially different from the topology of the bottom surface.

2. A package according to claim 1, wherein at least one electrically conductive portion on the top surface is connected to at least one electrically conductive portion on the bottom surface.

3. A package according to claim 1, further comprising:
a device cover coupled to the leadframe base, the cover and the base together defining an interior volume containing one or more MEMS devices.

4. A package according to claim 3, wherein the device cover shields devices within the interior volume from electromagnetic interference.

5. A package according to claim 3, wherein at least one of the device cover and the leadframe base includes an opening adapted to allow sound to enter the interior volume.

6. A package according to claim 1, further comprising:
a MEMS microphone die coupled to the leadframe base.

7. A package according to claim 6, further comprising:
an ASIC die coupled to the leadframe base.

8. A method of developing a package for a micro-electromechanical (MEMS) device, the method comprising:
developing a premolded leadframe base having opposing top and bottom surfaces, each surface being defined by a topology having at least one electrically conductive portion and at least one electrically non-conductive portion,
wherein the topology of the top surface is substantially different from the topology of the bottom surface.

9. A method according to claim 8, wherein at least one electrically conductive portion on the top surface is connected to at least one electrically conductive portion on the bottom surface.

10. A method according to claim 8, further comprising:
coupling a device cover to the leadframe base such that the cover and the base together define an interior volume containing one or more MEMS devices.

11. A method according to claim 10, wherein the device cover shields devices within the interior volume from electromagnetic interference.

12. A method according to claim 10, further comprising:
including in at least one of the device cover and the leadframe base an opening adapted to allow sound to enter the interior volume.

13. A method according to claim 8, further comprising:
coupling a MEMS microphone die to the leadframe base.

14. A method according to claim 13, further comprising:
coupling an ASIC die to the leadframe base.

15. A package for a micro-electromechanical (MEMS) device comprising:
means for developing a premolded leadframe base having opposing top and bottom surfaces, each surface being defined by a topology having at least one electrically conductive portion and at least one electrically non-conductive portion,
wherein the topology of the top surface is substantially different from the topology of the bottom surface.

16. A package according to claim 15, wherein at least one electrically conductive portion on the top surface is connected to at least one electrically conductive portion on the bottom surface.

17. A package according to claim 15, further comprising:
means for coupling a device cover to the leadframe base such that the cover and the base together define an interior volume containing one or more MEMS devices.

18. A package according to claim 17, wherein the device cover shields devices within the interior volume from electromagnetic interference.

19. A package according to claim 15, further comprising:
means for including in at least one of the device cover and the leadframe base an opening adapted to allow sound to enter the interior volume.

20. A package according to claim 15, further comprising:
means for coupling a MEMS microphone die to the leadframe base.

21. A package according to claim 20, further comprising:
means for coupling an ASIC die to the leadframe base.
